(19) United States
(12) Patent Application Publication
(10) Pub. No.: US 2022/0325437 A1
(43) Pub. Date: Oct. 13, 2022

(54) METHOD OF MANUFACTURING AND GROUP III NITRIDE CRYSTAL

(71) Applicant: Panasonic Holdings Corporation, Osaka (JP)

(72) Inventors: Yusuke MORI, Suita-shi (JP); Masashi YOSHIMURA, Suita-shi (JP); Masayuki IMANISHI, Suita-shi (JP); Shigeyoshi USAMI, Suita-shi (JP); Akira KITAMOTO, Suita-shi (JP); Junichi TAKINO, Osaka (JP)

(73) Assignee: Panasonic Holdings Corporation, Osaka (JP)

(21) Appl. No.: 17/717,446

(22) Filed: Apr. 11, 2022

(30) Foreign Application Priority Data
Apr. 12, 2021 (JP) 2021-067209

(51) Int. Cl. C30B 25/18; C30B 29/40; C30B 29/66

(52) U.S. Cl. CPC C30B 25/186; C30B 29/406; C30B 29/66; F21K 2/00

(57) ABSTRACT

A method of manufacturing a group III nitride crystal includes: preparing a seed substrate; causing surface roughness on the surface of the seed substrate; and supplying a group III element oxide gas and a nitrogen element-containing gas to grow a group III nitride crystal on the seed substrate.

### CROSS-REFERENCE TO RELATED APPLICATIONS

This application claims a priority of Japanese Patent Application No. 2021-67209 filed on Apr. 12, 2021, the contents of which is incorporated herein by reference.

### BACKGROUND

### 1. Technical Field

The present invention relates to a method of manufacturing a group III nitride crystal and a group III nitride crystal manufactured by this manufacturing method.

### 2. Description of the Related Art

Group III nitride crystals of GaN etc. are expected to be applied to next-generation optical devices such as high-output LEDs (light emitting diodes) and LDs (laser diodes), and next-generation electronic devices such as high-output power transistors mounted on EVs (electric vehicles) and PHVs (plug-in hybrid vehicles). An Oxide Vapor Phase Epitaxy (OVPE) method using a group III oxide as a raw material is used as a method of manufacturing a group III nitride crystal (see, e.g., WO 2015/053341A1). An example of a reaction system in the OVPE method is as follows. Ga is heated, and H₂O gas is introduced in this state. The introduced H₂O gas reacts with Ga to generate Ga₂O gas (see Formula (I)). NH₃ gas is introduced and reacted with the generated Ga₂O gas to generate a GaN crystal on a seed substrate (see Formula (II)).

2Ga(l)+H₂O(g)→Ga₂O(g)+H₂(g) (I)

Ga₂O(g)+2NH₃(g)→2GaN(s)+H₂O(g)+2H₂(g) (II)

However, in the manufacturing method described in WO 2015/053341A1, a hexagonal or dodecagonal inverted pyramid-shaped pit having {10-1n} or {11-2m} as a principal surface is generated from a region starting from a dislocation defect; however, a pit is hardly generated from the other regions. Therefore, when a high-quality seed substrate with a low dislocation density is used, the number of pits generated in the region starting from a dislocation defect is reduced due to the small number of dislocation defects, and a density of pits generated in a growth layer of a group III nitride crystal becomes small.

When the pit density is small, unevenness on the surface of the grown group III nitride crystals tends to be large. Therefore, a size of each pit tends to be large. Thus, when a group III nitride crystal is grown on a seed substrate having a lattice plane (0001) as a principal surface, the orientation of the tile component thereof may decrease. The orientation of the tilt component is, for example, a distortion of the (0001) plane in the case of a crystal having the lattice plane (0001) as a principal surface. FIG. 1 shows a conceptual diagram of the orientation of the tilt component in the cases of large and small pit densities attributable to dislocation defects. FIG. 1A is a cross-sectional conceptual diagram showing a relationship between a dislocation defect of a grown crystal on a low dislocation density substrate and a strain of a lattice plane. FIG. 1B is a cross-sectional conceptual diagram showing a relationship between a dislocation defect of a grown crystal on a high dislocation density substrate and a strain of a lattice plane. As shown in FIGS. 1A and 1B, the grown crystal on the low dislocation density substrate tends to have a large strain on the lattice plane, and the orientation of the tilt component becomes lower.

When a group III nitride substrate is produced from a grown group III nitride crystal and a device is produced on the group III nitride substrate, a device layer of the group III nitride crystal is formed on the group III nitride substrate. The device layer of the group III nitride crystal is affected by the orientation of the group III nitride substrate. Therefore, when the orientation of the tilt component of the group III nitride substrate is low, the orientation of the device layer of the group III nitride crystal is also low. If the orientation of the tilt component of the device layer is low, the performance of the device may not be fully exhibited when the device is driven. Therefore, to obtain a high-quality group III nitride crystal, it is necessary to enhance the orientation of the tilt component.

When the density of the pits is small, as shown in FIG. 1A above, the unevenness on the surface of the grown group III nitride crystal tends to be large. When cutting out a wafer from a grown group III nitride crystal, it is generally necessary to remove this surface unevenness, therefore, if the surface unevenness is large, a portion of the grown group III nitride crystal to be removed may become large. Therefore, this causes a problem that the lower the dislocation density of the seed substrate, the larger the material loss when the group III nitride substrate is produced from the group III nitride crystal. On the other hand, as shown in FIG. 1B, when a seed substrate having a high dislocation density is used, the unevenness of the surface becomes small and the portion to be removed is reduced; however, in this case, the quality becomes low due to the high dislocation density. As described above, it is not easy to reduce the material loss at the time of manufacturing of the group III nitride substrate and to manufacture a high-quality group III nitride crystal.

### SUMMARY

The present disclosure was conceived in view of the situations, and it is therefore one non-limiting and exemplary embodiment provides a manufacturing method capable of reducing a material loss at the time of manufacturing of a group III nitride substrate and for obtaining a high-quality group III nitride crystal, and a group III nitride substrate.

In one general aspect, the techniques disclosed here feature: a method of manufacturing a group III nitride crystal, includes:

preparing a seed substrate;

causing surface roughness on the surface of the seed substrate; and

supplying a group III element oxide gas and a nitrogen element-containing gas to grow a group III nitride crystal on the seed substrate.

In another general aspect, the techniques disclosed here feature: a group III nitride crystal, on a smooth surface of the group III nitride crystal after surface polishing, includes:

multiple petal-shaped luminescence regions; and

multiple dislocation defects,

wherein the number of the petal-shaped luminescence regions is larger than the number of the dislocation defects.

According to the method for producing a group III nitride crystal according to the present disclosure, the material loss can be reduced at the time of manufacturing of the group III nitride substrate and the high-quality group III nitride crystal can be manufactured.

Additional benefits and advantages of the disclosed embodiments will be apparent from the specification and figures. The benefits and/or advantages may be individually provided by the various embodiments and features of the specification and drawings disclosure, and need not all be provided in order to obtain one or more of the same.

### BRIEF DESCRIPTION OF DRAWINGS

The present disclosure will become readily understood from the following description of non-limiting and exemplary embodiments thereof made with reference to the accompanying drawings, in which like parts are designated by like reference numeral and in which:

FIG. 1A is a cross-sectional conceptual diagram showing a relationship between a dislocation defect of a grown crystal on a low dislocation density substrate and a strain of a lattice plane;

FIG. 1B is a cross-sectional conceptual diagram showing a relationship between a dislocation defect of a grown crystal on a high dislocation density substrate and a strain of a lattice plane;

FIG. 2A is a flowchart showing a time-series manufacturing method of a group III nitride crystal according to a first embodiment of the present disclosure;

FIG. 2B is a flowchart when functional units from the upstream to the downstream in a manufacturing apparatus used in the manufacturing method are shown as steps;

FIG. 3 is a schematic cross-sectional view showing a cross-sectional configuration of a group III nitride crystal manufacturing apparatus used in the method of manufacturing a group III nitride crystal according to the first embodiment of the present disclosure;

FIG. 4A is a cross-sectional conceptual diagram showing a relationship with surface unevenness when a surface roughness step is not included in the method of manufacturing a group III nitride crystal;

FIG. 4B is a cross-sectional conceptual diagram showing a relationship with the surface unevenness when a surface roughness step is included in the method of manufacturing a group III nitride crystal;

FIGS. 5A-5C are graphs showing pit density (FIG. 5A), pit depth (FIG. 5B), and (0002) plane X-ray locking curve half-value width (FIG. 5C) of Examples and Comparative Examples;

FIG. 6A is a surface optical microscope image after surface smoothing of a GaN crystal manufactured through the surface roughness step; and

FIG. 6B is a photoluminescence image after surface smoothing of a GaN crystal manufactured through the surface roughness step.

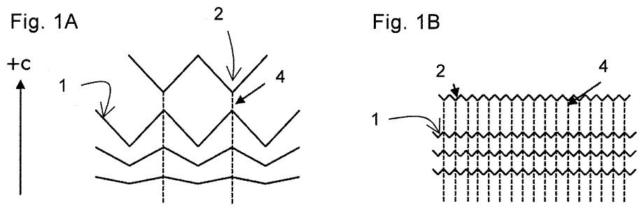

### DETAILED DESCRIPTION

A method of manufacturing a group III nitride crystal according to a first aspect, includes:

preparing a seed substrate;

causing surface roughness on the surface of the seed substrate; and

supplying a group III element oxide gas and a nitrogen element-containing gas to grow a group III nitride crystal on the seed substrate.

Further, as a method of manufacturing a group III nitride crystal of a second aspect, in the first aspect, in the cause of causing surface roughness, the surface of the seed substrate is roughened in a temperature raising process of 900° C. or higher and lower than 1500° C. before growing the group III nitride crystal.

A group III nitride crystal, on a smooth surface of the group III nitride crystal after surface polishing, according to a third aspect, includes:

multiple petal-shaped luminescence regions; and

multiple dislocation defects,

wherein the number of the petal-shaped luminescence regions is larger than the number of the dislocation defects.

Further, as a group III nitride crystal of a fourth aspect, in the third aspect, the petal-shaped luminescence regions are confirmable by photoluminescence, and wherein the dislocation defects are confirmable by a surface optical microscope image after alkali melt etching.

A method of manufacturing a group III nitride crystal and the group III nitride crystal according to embodiments will be described with reference to the accompanying drawings. In the drawings, substantially the same members are denoted by the same reference numerals.

### First Embodiment

### <Overview of Group III Nitride Crystal Manufacturing Apparatus>

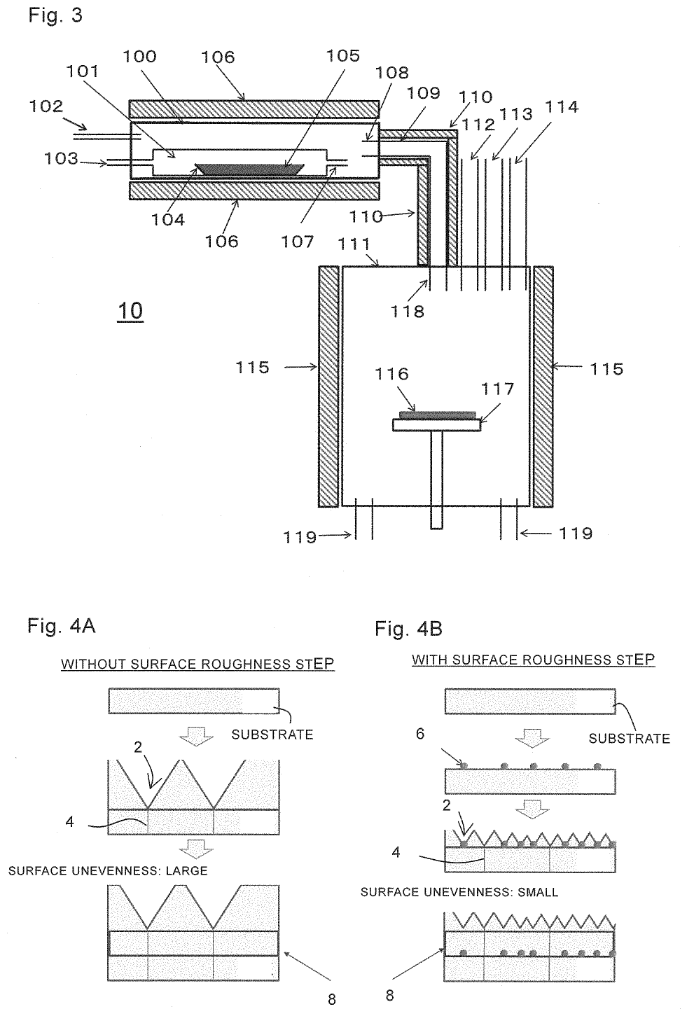

An overview of a manufacturing apparatus of a group III nitride crystal according to this embodiment will be described with reference to FIG. 3. FIG. 3 is a schematic cross-sectional view showing a cross-sectional configuration of a group III nitride crystal manufacturing apparatus 10. Constituent members shown in FIG. 3 may be different from actual members in terms of size, ratio, etc.

The group III nitride crystal manufacturing apparatus 10 has a raw material chamber 100 and a growth chamber 110. A raw material reaction chamber 101 is disposed in the raw material chamber 100, and a raw material boat 104 with a starting group III element source 105 placed therein is disposed in the raw material reaction chamber 101. A reactive gas supply pipe 103 supplying a reactive gas reactive with the starting group III element source 105 is connected to the raw material reaction chamber 101. The raw material reaction chamber 101 has a group III element oxide gas discharge port 107 discharging a generated group III element oxide gas. When the starting group III source is an oxide, a reducing gas is used as the reactive gas. When the starting group III source is a metal, an oxidizing gas is used as the reactive gas.

The raw material chamber 100 is connected to a first carrier gas supply port 102 to which a first carrier gas is supplied. The first carrier gas supplied from the first carrier gas supply port 102 and the group III element oxide gas discharged from the group III element oxide gas discharge port 107 flow from a gas discharge port 108 through a connection pipe 109 into a growth chamber 111. The first carrier gas and the group III element oxide gas are supplied into the growth chamber 111 from a gas supply port 118 connected to the growth chamber 111.

The growth chamber 111 has a gas supply port 118, a third carrier gas supply port 112, a nitrogen element-containing gas supply port 113, a second carrier gas supply port 114, and an exhaust port 119. The growth chamber 111 includes a substrate susceptor 117 on which a seed substrate 116 is disposed.

### <Overview of Manufacturing Method of Group III Nitride Crystal>

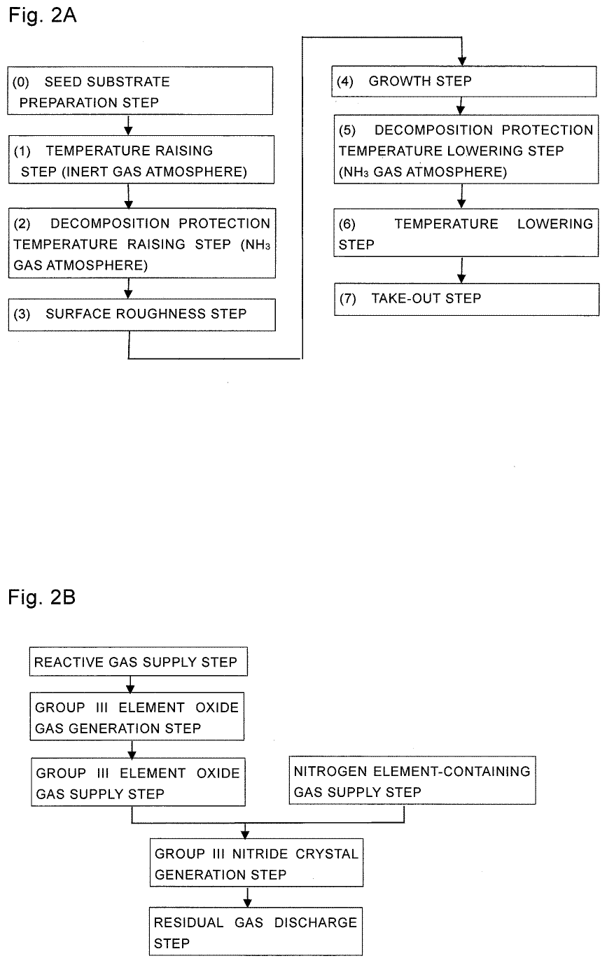

An overview of a method of manufacturing a group III nitride crystal according to this embodiment will be described with reference to a flowchart of FIGS. 2A and 2B. FIG. 2A shows a time-series flowchart of the manufacturing method. FIG. 2B shows functional units from upstream to downstream in the manufacturing apparatus used in this manufacturing method as steps. This method of manufacturing a group III nitride crystal includes: preparing a seed substrate; causing surface roughness on the surface of the seed substrate, and supplying a group III element oxide gas and a nitrogen element-containing gas to grow a group III nitride crystal on the seed substrate.

The steps will be described in time series.

(0) In a seed substrate preparation step of preparing the seed substrate 116, the seed substrate 116 is placed on the substrate susceptor 117.

(1) In the first embodiment, the method of manufacturing a group III nitride crystal includes a temperature raising step. In the temperature raising step, the temperature of the growth chamber 111 is raised to 100° C. or higher and lower than 500° C. in an inert gas atmosphere.

(2) In the first embodiment, the method of manufacturing a group III nitride crystal includes a decomposition protection temperature raising step. In the decomposition protection temperature raising step, the temperature of the growth chamber 111 is raised to 500° C. or higher and lower than 1000° C. in an NH₃ gas atmosphere.

(3) In the surface roughness step of causing the surface roughness on the surface of the seed substrate 116, the temperature of the growth chamber 111 is raised to 900° C. or higher and lower than 1500° C. in an NH₃ gas atmosphere.

(4) In the growth step of growing a group III nitride crystal on the seed substrate 116, the group III element oxide gas is generated in the raw material chamber 100 and supplied to the growth chamber 111, and the nitrogen element-containing gas is supplied to the growth chamber 111 to generate the group III nitride crystal on the seed substrate 116.

As shown in FIG. 2B, this growth step includes a reactive gas supply step, a group III element oxide gas generation step, a group III element oxide gas supply step, a nitrogen element-containing gas supply step, a group III nitride crystal generation step, and a residual gas discharge step. The steps included in the growth step may simultaneously be performed in the group III nitride crystal manufacturing apparatus.

(4-1) In the reactive gas supply step, the reactive gas is supplied to the raw material reaction chamber.

(4-2) In the group III element oxide gas generation step, a starting group III element source and a reactive gas (a reducing gas when the starting group III element source is an oxide, an oxidizing gas when the source is a metal) are reacted to generate the group III element oxide gas.

(4-3) In the group III element oxide gas supply step, the group III element oxide gas produced in the group III element oxide gas generation step is supplied to the growth chamber.

(4-4) In the nitrogen element-containing gas supply step, the nitrogen element-containing gas is supplied to the growth chamber.

(4-5) In the group III nitride crystal generation step, the group III element oxide gas supplied into the growth chamber in the group III element oxide gas supply step is reacted with the nitrogen element-containing gas supplied into the growth chamber in the nitrogen element-containing gas supply step to grow a group III nitride crystal on the seed substrate.

(4-6) In the residual gas discharge step, unreacted gas not contributing to the formation of group III nitride crystal is discharged to the outside of the chamber.

(5) In the first embodiment, the method of manufacturing a group III nitride crystal includes a decomposition protection temperature lowering step. In the decomposition protection temperature lowering step, the temperatures of the raw material chamber 100 and the growth chamber 111 are lowered to 500° C. while supplying NH₃ gas so as to suppress the decomposition of the group III nitride crystal grown on the seed substrate 116.

(6) In the first embodiment, the method of manufacturing a group III nitride crystal includes a temperature lowering step. In the temperature lowering step, the temperatures of the raw material chamber 100 and the growth chamber 111 are lowered to less than 100° C. in an inert gas atmosphere.

(7) In the first embodiment, the method of manufacturing a group III nitride crystal includes a take-out step. In the take-out step, the seed substrate 116 having the group III nitride crystal grown thereon is taken out from the growth chamber 111.

### <Details of Manufacturing Method and Manufacturing Apparatus of Group III Nitride Crystal>

A method of manufacturing a group III nitride crystal according to the first embodiment will be described in detail with reference to FIGS. 2 and 3.

In the first embodiment, metal Ga is used as the starting group III element source 105; however, the present invention is not limited thereto, and for example, Al or In may be used.

(0) First, the seed substrate 116 is prepared. For the seed substrate 116, for example, gallium nitride, gallium arsenide, silicon, sapphire, silicon carbide, zinc oxide, gallium oxide, or ScAlMgO₄ can be used. In the first embodiment, gallium nitride is used for the seed substrate 116.

(1) In the temperature raising step, the temperature of the growth chamber is raised to a temperature at which the seed substrate 116 does not decompose in an inert gas atmosphere. In the manufacturing of a group III nitride crystal by the OVPE method, heating is performed to about 500° C. in an atmosphere of an inert gas (e.g., N₂ gas).

(2) In the decomposition protection temperature raising step, the temperature is raised while suppressing the decomposition of the seed substrate 116 in a nitrogen element-containing gas atmosphere. In the manufacturing of a group III nitride crystal by the OVPE method, heating is performed from 500° C. to lower than 900° C. in a state where the inert gas and the nitrogen element-containing gas (NH₃ gas) are mixed. The reason for mixing NH₃ is to prevent the seed substrate 116 from being decomposed due to desorption of N atoms.

(3) In the surface roughness step of forming the surface roughness of the seed substrate 116, the surface of the seed substrate 116 is roughened so as to increase a density of pits generated on the surface of the group III nitride crystal to be grown and to reduce a size of each pit. When gallium nitride having a lattice plane (0001) as a principal surface is used for the seed substrate, pits are generated from starting points that are dislocation defects of the seed substrate on the surface of the group III nitride crystal grown by the OVPE method. A pit is a pyramid-shaped depression covered with surfaces having an angle inclined from the (0001) plane and is made up of planes inclined from the a-plane or m-plane such as {10-11} and {11-22}. Therefore, when gallium nitride having a low dislocation density is used as a seed substrate, the surface unevenness tends to be large due to a low pit density. Therefore, when a group III nitride substrate is cut out from the group III nitride crystal to form a wafer, the unevenness to be removed becomes large, so that a material loss may increase.

FIG. 4A is a cross-sectional conceptual diagram showing a relationship with the surface unevenness when the surface roughness step is not included in the method of manufacturing a group III nitride crystal. FIG. 4B is a cross-sectional conceptual diagram showing a relationship with the surface unevenness when the surface roughness step is included in the method of manufacturing a group III nitride crystal.

As shown in FIG. 4A, when surface of the seed substrate is not roughened, in the case of using a seed substrate having a low dislocation density, for example, a seed substrate having a dislocation density of 1×10⁴/cm², Pits 2 are generated at intervals of 100 μm square. Therefore, the pits 2 having a diameter of 100 μm is generated. Assuming that diagonal facets are formed by {10-11}, the depth of the pit 2 is 94 μm, and even in the case of growing to a thickness of 400 μm, which is the standard thickness for wafer formation, ¼ of the thickness is a region that cannot be used as a wafer.

On the other hand, as shown in FIG. 4B, the pit 2 can be generated in a region other than the dislocation defect 4 by causing the surface roughness on the surface of the seed substrate 116 before growing the group III nitride crystal. When the surface roughness 6 is caused on the seed substrate 116, the pits 2 can be generated even in the region without the dislocation defect 4, so that the pits 2 increase as a whole and the pit density becomes higher. Therefore, when the group III nitride crystal is grown, the unevenness on the surface thereof becomes small, and a wasteful region can be reduced when the wafer is cut out.

The step of causing the surface roughness is performed by using the manufacturing apparatus used for manufacturing the group III nitride crystal and may be introduced into a series of steps for growing the group III nitride crystal. To intentionally cause the surface roughness in the manufacturing of the group III nitride crystal by the OVPE method, a surface roughness process may be introduced in which heating is performed in an atmosphere of only inert gas and NH₃ gas at 900° C. or higher and lower than 1500° C. As a result, the GaN crystal surface of the seed substrate 116 before start of bulk growth of the group III nitride crystal started at 1200° C. or higher can be put into a state where pits are generated even in regions other than the dislocation defects. The surface roughness process may be performed at a stage of preparing the seed substrate, or the surface roughness may be caused by wet etching using an alkali or an acid.

In this case, to prevent the nitrogen element-containing gas from being decomposed by heat from the growth chamber 111, the outer walls of the nitrogen element-containing gas supply port 112 and the growth chamber 111 are preferably covered with a heat insulating material.

A second carrier gas may be supplied from the second carrier gas supply port 114 to the growth chamber 111 to control the concentrations of the group III element oxide gas and the nitrogen element-containing gas. In this case, parasitic growth of the group III nitride crystal can be suppressed on the furnace wall of the growth chamber 111 and the substrate susceptor 117. To suppress the parasitic growth on the substrate susceptor 117, it is desirable that the material of the substrate susceptor 117 is an active metal. Furthermore, from the viewpoint of suppressing alloying with Ga, it is more desirable that the material of the substrate susceptor 117 is Mo or Pt.

An inert gas, H₂ gas, etc. can be used as the second carrier gas.

(4) In the growth step, the group III element oxide gas is generated in the raw material chamber 100 and supplied to the growth chamber 111, and the nitrogen element-containing gas is supplied to the growth chamber 111 to generate the group III nitride crystal on the seed substrate 116. Specifically, as shown in FIG. 2B, the growth steps include a reactive gas supply step, a group III element oxide gas generation step, a group III element oxide gas supply step, a nitrogen element-containing gas supply step, a group III nitride crystal generation step, and a residual gas discharging step.

(4-1) In the reactive gas supply step, the reactive gas is supplied from the reactive gas supply pipe 103 to the raw material reaction chamber 101 in the raw material chamber 100. As described above, a reducing gas or an oxidizing gas can be used as the reactive gas as appropriate. In this embodiment, since the metal Ga is used as the group III element source 105, H₂O gas is used as the reactive gas.

(4-2) In the group III element oxide gas generation step, the reactive gas supplied to the raw material reaction chamber 101 in the reactive gas supply step reacts with Ga serving as the starting group III element source 105 to generate Ga₂O gas that is the group III element oxide gas. The generated Ga₂O gas is discharged from the raw material reaction chamber 101 to the raw material chamber 100 through the group III element oxide gas discharge port 107. The discharged Ga₂O gas is mixed with the first carrier gas supplied from the first carrier gas supply port 102 to the raw material chamber and is supplied to the gas discharge port 108. In this embodiment, the raw material chamber 100 is heated by a first heater 106. When the raw material chamber 100 is heated, the temperature of the raw material chamber 100 is preferably 800° C. or higher from the viewpoint of the boiling point of the Ga₂O gas. Additionally, the temperature of the raw material chamber 100 is preferably made lower than that of the growth chamber 111. When the growth chamber is heated by a second heater 115 as described later, the temperature of the raw material chamber 100 is preferably made lower than 1800° C., for example. The starting group III element source 105 is placed in the raw material boat 104 disposed in the raw material reaction chamber 101. The raw material boat 104 preferably has a shape capable of increasing a contact area between the reactive gas and the starting group III element source. For example, the raw material boat 104 preferably has a multi-stage dish shape so as to prevent the starting group III element source 105 and the reactive gas from passing through the raw material reaction chamber 101 in a non-contact state.

Methods of generating the group III element oxide gas are roughly classified into a method of reducing the starting group III element source 105 and a method of oxidizing the starting group III element source 105. For example, in the reducing method, an oxide (e.g., Ga₂O₃) is used as the starting group III element source 105, and a reducing gas (e.g., H₂ gas, CO gas, CH₄ gas, C₂H₆ gas, H₂S gas, SO₂ gas) is used as the reactive gas. On the other hand, in the oxidizing method, the starting group III element source 105 is a non-oxide (e.g., liquid Ga), and an oxidizing gas (e.g., H₂O gas, O₂ gas, CO gas, CO₂ gas, NO gas, N₂O gas, NO₂ gas) is used as the reactive gas. In addition to the starting group III element source 105, an In source and an Al source can be adopted as the starting group III element. An inert gas, H₂ gas, etc. can be used as the first carrier gas.

(4-3) In the group III element oxide gas supply step, the Ga₂O gas generated in the group III element oxide gas generation step is supplied through the gas discharge port 108, the connection pipe 109, and the gas supply port 118 to the growth chamber 111. When the temperature of the connection pipe 109 connecting the raw material chamber 100 and the growth chamber 111 is lower than the temperature of the raw material chamber 100, a reverse reaction of the reaction for generating the group III element oxide gas occurs, and the starting Ga source 105 precipitates inside the connection pipe 109. Therefore, the connection pipe 109 is preferably heated by a third heater 110 to a temperature higher than that of the first heater 106 so as to prevent the temperature from becoming lower than the temperature of the raw material chamber 100.

(4-4) In the nitrogen element-containing gas supply step, the nitrogen element-containing gas is supplied from the nitrogen element-containing gas supply port 113 to the growth chamber 111. Examples of the nitrogen element-containing gas include NH₃ gas, NO gas, NO₂ gas, N₂O gas, N₂H₂ gas, and N₂H₄ gas.

In the group III nitride crystal generation step, the raw material gas supplied into the growth chamber through the supply steps is reacted to grow the group III nitride crystal on the seed substrate 116. The growth chamber 111 is preferably heated by the second heater 115 to a temperature at which the group III element oxide gas reacts with the nitrogen element-containing gas. In this case, to prevent the reverse reaction of the reaction for generating the group III element oxide gas from occurring, the temperature of the growth chamber 111 is preferably controlled so that the temperature of the growth chamber 111 does not become lower than the temperature of the raw material chamber 100. The temperature of the growth chamber 111 heated by the second heater 115 is preferably 1000° C. or higher and 1800° C. or lower. The second heater 115 and the third heater 111 are preferably set to the same temperature so as to suppress temperature fluctuation of the growth chamber 111 due to the Ga₂O gas generated in the raw material chamber 100 and the first carrier gas.

(4-5) By mixing the group III element oxide gas supplied to the growth chamber 111 through the group III element oxide gas supply step and the nitrogen element-containing gas supplied to the growth chamber 111 through the nitrogen element-containing gas supply step upstream of the seed substrate 116, the group III nitride crystal can be grown on the seed substrate 116 (the group III nitride crystal generation step).

(4-6) In the residual gas discharge step, the unreacted group III element oxide gas and nitrogen element-containing gas, as well as the first carrier gas, the second carrier gas, and the third carrier gas are discharged from the exhaust port 119.

The reactive gas supply step, the group III element oxide gas generation step, the group III element oxide gas supply step, the nitrogen element-containing gas supply step, the group III nitride crystal generation step, and the residual gas discharge step included in the growth step may be performed at the same time.

(5) In the decomposition protection temperature lowering step, the temperature is lowered while suppressing the decomposition of the group III nitride crystal in a nitrogen element-containing gas atmosphere. In the manufacturing of the group III nitride crystal by the OVPE method, cooling is performed to 500° C. or lower in a mixed state of the inert gas and the nitrogen element-containing gas (NH₃ gas).

(6) In the temperature lowering step, the temperature is lowered to a temperature at which the group III nitride crystal can be taken out from the growth chamber in an inert gas atmosphere.

(7) In the first embodiment, the seed substrate 116 having the group III nitride crystals grown thereon through the temperature lowering step is taken out from the growth chamber 111 (take-out step).

From the above, a high-quality group III nitride crystal with high orientation of the tilt component can be obtained. Additionally, the material loss can be reduced when a group III nitride substrate is produced from the group III nitride crystal.

### Overview of Example and Comparative Example

A group III nitride crystal was grown by using the group III nitride crystal manufacturing apparatus that is the growth furnace shown in FIG. 3. GaN was grown as a group III nitride crystal. Liquid Ga was used as the starting group III element source, Ga was reacted with H₂O gas that is a reactive gas, and the generated Ga₂O gas was used as the group III element oxide gas. NH₃ gas was used as the nitrogen element-containing gas, and a mixture of H₂ gas and N₂ gas was used as the first carrier gas and the second carrier gas. The growth time was set to 3 hours for the verification. The surface pit density was measured by observing a surface of a grown crystal with a scanning electron microscope (SEM) and counting the number of pits (pits/cm²) per unit area. A GaN substrate with a lattice surface (0001) having a dislocation density on the level of 10⁵/cm² or more as a principal surface was used as the seed substrate 116. To evaluate the crystal orientation of the tilt component, the X-ray locking curve of the (0002) plane of the grown crystal was measured and evaluated from a half-value width.

### Example 1

For the growth conditions, the substrate temperature was 1200° C. and the raw material temperature was 1100° C. The Ga₂O gas partial pressure was 0.00079 atm, the H₂O gas partial pressure was 0.00035 atm, the NH₃ gas partial pressure was 0.15759 atm, the H₂ gas partial pressure was 0.71870 atm, and the N₂ gas partial pressure was 0.12257 atm. In a temperature raising process of 900° C. or higher and lower than 1500° C., a surface roughness process was introduced without supplying Ga₂O gas serving as the group III element oxide gas.

As a result of GaN growth, the thickness of the growth layer was 189 μm. The surface pit density was 2.6×10⁶/cm². The average pit diameter was 6.2 μm and the pit depth was 5.8 μm. The half-value width of the X-ray locking curve of the (0002) plane was 51 arcsec.

### Comparative Example 1

Although the growth conditions were the same as in Example 1, GaN crystal growth was performed in the temperature raising process of 900° C. or higher and lower than 1500° C. without introducing the surface roughness process.

As a result of GaN growth, the thickness of the growth layer was 184 μm. The surface pit density was 1.1×10⁵/cm². The average pit diameter was 30 μm and the pit depth was 28.2 μm. The half-value width of the X-ray locking curve of the (0002) plane was 79 arcsec.

### Summary of Example and Comparative Example

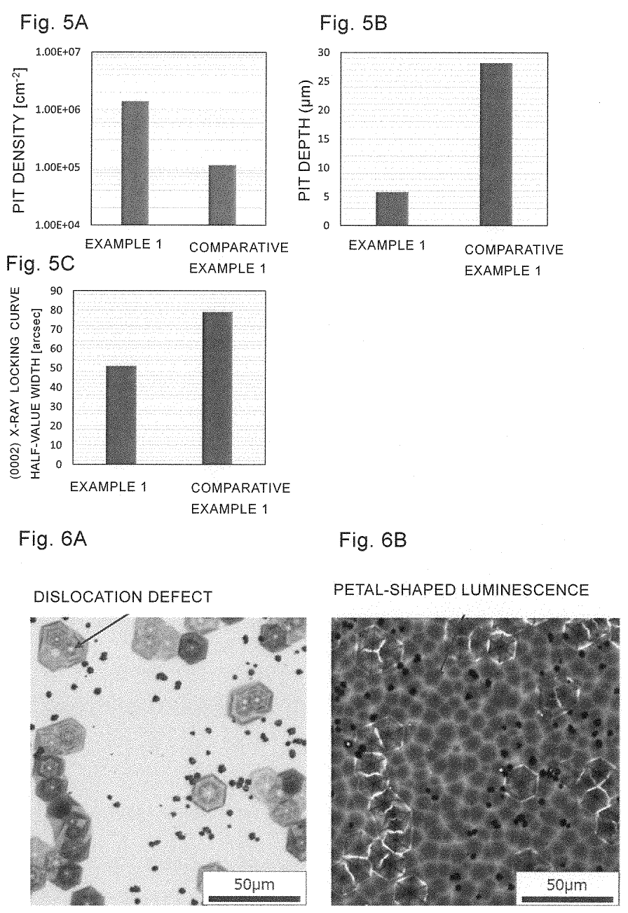

FIGS. 5A-5C show the evaluation results of the surface pit density, the pit depth, and the half-value width of the X-ray locking curve of Example and Comparative Example. The surface roughness process for the seed substrate was introduced in Example 1, and the process was not introduced in Comparative Example 1. As can be seen from FIG. 5A, the pit density is larger in Example 1 in which the surface roughness process was introduced. As shown in FIG. 5B, the pit depth in Example 1 is smaller than that in Comparative Example 1. From these results, it can be seen that the surface roughness can be reduced by introducing the surface roughness process. Therefore, it was demonstrated that when a wafer of a group III nitride substrate is produced from the group III nitride crystals obtained in Example 1, the surface unevenness to be removed is reduced as compared to Comparative Example 1 and the material loss can be reduced.

Further, as can be seen from the evaluation result of the half-value width of the X-ray locking curve shown in FIG. 5C, the pit density was increased to reduce the surface unevenness in Example 1, the orientation of the tilt component is improved. From this result, it was demonstrated that the crystal quality is improved when the surface roughness process was introduced.

Furthermore, from the analysis of the grown crystal subjected to the surface roughness process, a history of pit generation is confirmed even in a region without a dislocation defect. FIGS. 6A and 6B show a surface optical microscope image and a photoluminescence (PL) image of the same location of a grown crystal after smooth polishing, after etching with a mixed melt of sodium hydroxide and potassium hydroxide. Due to etching with the mixed melt, a hexagonal pyramid-shaped etch pit is formed in a region where the dislocation defect exists as shown in FIG. 6A. On the other hand, when the PL image of FIG. 6B is checked, petal-shaped luminescence is confirmed even in a region where the dislocation defect does not exist, i.e., a region where the etch pit is not generated. This petal-shaped luminescence reflects a history of a pit generated at the time of crystal growth. Therefore, it is understood that by introducing the surface roughness process, a pit can be generated even in a region where no dislocation defect exists, i.e., a region where the etch pit is not generated. In the obtained group III nitride crystal, the number of petal-shaped luminescence regions, i.e., the number of pits, is larger than the number of dislocation defects on the smooth surface after surface polishing.

As described above, according to the method of manufacturing a group III nitride crystal according to the first embodiment and Example 1, pits are generated without increasing dislocation defects to grow the group III nitride crystal so that the unevenness of the surface can be reduced. Therefore, a material loss can be reduced at the time of cutting out of a group III nitride substrate, and the high-quality group III nitride crystal can be manufactured.

The present disclosure includes appropriately combining any embodiments and/or examples out of the various embodiments and/or examples described above, and the effects of the respective embodiments and/or examples can be produced.

According to the method of manufacturing a group III nitride crystal according to the present invention, a material loss can be reduced at the time of manufacturing of a group III nitride substrate, and a high-quality group III nitride crystal can be manufactured.

### EXPLANATIONS OF LETTERS OR NUMERALS

1 lattice plane
2 pit
4 dislocation defect
6 surface roughness
8 cut-out wafer
10 group III nitride crystal manufacturing apparatus
100 raw material chamber
101 raw material reaction chamber
102 first carrier gas supply port
103 reactive gas supply pipe
104 raw material boat
105 starting group III element source
106 first heater
107 group III element oxide gas discharge port
108 gas discharge port
109 connection pipe
110 third heater
111 growth chamber
112 third carrier gas supply port
113 nitrogen element-containing gas supply port
114 second carrier gas supply port
115 second heater
116 seed substrate
117 substrate susceptor
118 gas supply port
119 exhaust port

What is claimed is:

1. A method of manufacturing a group III nitride crystal, comprising:
preparing a seed substrate;
causing surface roughness on the surface of the seed substrate; and
supplying a group III element oxide gas and a nitrogen element-containing gas to grow a group III nitride crystal on the seed substrate.

2. The method of manufacturing a group III nitride crystal according to claim 1, wherein in the cause of causing surface roughness, the surface of the seed substrate is roughened in a temperature raising process of 900° C. or higher and lower than 1500° C. before growing the group III nitride crystal.

3. A group III nitride crystal, on a smooth surface of the group III nitride crystal after surface polishing, comprising:
multiple petal-shaped luminescence regions; and
multiple dislocation defects,
wherein the number of the petal-shaped luminescence regions is larger than the number of the dislocation defects.

4. The group III nitride crystal according to claim 3, wherein the petal-shaped luminescence regions are confirmable by photoluminescence, and wherein the dislocation defects are confirmable by a surface optical microscope image after alkali melt etching.
